(19) United States
(12) Patent Application Publication
(10) Pub. No.: US 2010/0236479 A1
(43) Pub. Date: Sep. 23, 2010

(54) PLASMA DEPOSITION APPARATUS

(76) Inventor: Stephen Richard Coulson, Oxford (GB)

Correspondence Address: Manelli Denison & Selter PLLC;Attn: William H. Bollman, 2000 M Street, NW, 7th Floor, Wasgington, DC, 20036, US

(21) Appl. No.: 12/734,513

(22) PCT Filed: Nov. 7, 2008
(86) PCT No.: PCT/GB2008/003739

§ 371 Date: May 17, 2010

(30) Foreign Application Priority Data
Nov. 7, 2007 (GB) 0721771.4

(51) Int. Cl. C23C 16/00

(52) U.S. Cl. 118/723 R

(57) ABSTRACT

Apparatus (10) is shown for plasma treating a surface of a small (channel 12) to modify the surface and change the functional effect. The apparatus comprises: a source (14) of active species for supply to an inlet (16) of a processing region (18) for forming a plasma in the processing region; means (20) for applying an electric field to the active species in the processing region so that a plasma is formed; and vacuum pumping means (22) for connection to an outlet (24) of the processing region. The vacuum pumping means are operable to provide a flow path (26) in the processing region from the inlet to the outlet thereof and to control pressure in the processing region. Apparatus (10) further comprises supporting means for supporting at least one small channel so that, in use, the flow path extends therethrough, and an internal surface of said at least one small channel is coated with a thin film polymer layer by plasma deposition.

### FIELD OF THE INVENTION

This invention relates to apparatus for treating a surface of a small channel by plasma processing.

### BACKGROUND OF THE INVENTION

Pipes, tubes and other small channels are desirable for transporting gases and liquids due to their optimal geometry for manufacture and functionality. Often the materials used to manufacture such small channels are selected for reasons such as cost, strength, flexibility, inertness, weight etc. However, the internal surface of the small channels may react with the medium being transported unfavourably and may, for instance, cause fouling, resulting in a less than optimised product that may be unable to carry out the desired operation, requires constant maintenance or needs to be replaced regularly.

### PRIOR ART

Creating a desirable internal surface using a range of methods has been addressed in areas such as oil field pipes, or other applications, e.g. U.S. Pat. No. 424,369, U.S. Pat. No. 4,382,421, U.S. Pat. No. 4,698,241 and RU2212283. These approaches appear feasible for large diameter, metallic products, however on miniaturisation of channels particularly for medical, lab-on-chip and microfluidic devices, for example, the processes described are inadequate for functionalising the internal surface of the channels.

Techniques such as dip coating have been used to try to overcome unfavourable interactions between the internal surface of small channels and the medium being transported however as the tube diameter decreases dip coating becomes ineffective.

US Patent Application US2005/0022561 (Guskov et al) discloses a ring plasma jet for producing an optical pre-form. A plasma flame is generated on an interior volume of a tubular member so as to deposit soot particles on an inner surface thereof. Selective location of the plasma field is achieved by directing an electromagnetic field in a fibre optic preform.

Japanese Patent Application JP-A-3275137 (Bridgestone Corp) discloses a method of forming a pre-form by producing a low temperature plasma in a hollow material by way of a plasma forming device and a high-conductivity insert.

The systems described above do not address rapid through-put of small diameter, long channelled products, through treatment by, for example, the attachment of an ultra thin, well adhered polymer layer, independent of substrate material to products such as catheters, hypodermic needles, housed filtration elements and microfluidic devices. Instead they are directed to the fabrication of optical fibres.

Known techniques also do not readily lend themselves to rapid treatment of multiple articles in a commercially viable production line and it is an object of the invention to overcome this.

### SUMMARY OF THE INVENTION

According to the present invention there is provided an apparatus for treating a surface of a small channel by plasma processing, the apparatus comprising:
a source of active species for supply to an inlet of a processing region for forming a plasma in said processing region;
means for applying an electric field to the active species in said processing region so that a plasma is formed;
vacuum pumping means for connection to an outlet of the processing region, said vacuum pumping means being operable to provide a flow path in said processing region from the inlet to the outlet thereof and to control pressure in said processing region; and
supporting means for supporting at least one small channel so that, in use, said flow path extends therethrough, and an internal surface of said at least one small channel is treated by plasma processing.

The monomer itself is not active. It becomes activated in the plasma when the predetermined conditions are achieved.

Other preferred and/or optional features of the invention are defined in the accompanying claims.

The invention will now be described, by way of example only, with reference to the accompanying drawings, in which:

### BRIEF DESCRIPTION OF THE DRAWINGS

FIG. 1 is a schematic representation of an apparatus for plasma processing a surface of a small channel;

FIGS. 2 to 6 show various different arrangements of small channels in a processing region of the apparatus of FIG. 1;

FIG. 7 shows an inlet support for receiving and supporting small channels;

FIG. 8 shows another arrangement of the apparatus shown in FIG. 1;

FIG. 9 shows a modified version of the inlet support shown in FIG. 7;

FIG. 10 shows the inlet support in a further arrangement of the apparatus shown in FIG. 1;

FIG. 11 shows a still further arrangement of the apparatus shown in FIG. 1; and

FIG. 12 shows a modified inlet support and arrangement for supplying active species to a processing region.

### DETAILED DESCRIPTION OF THE ILLUSTRATED EMBODIMENTS

As referred to herein, treating a surface by plasma processing includes for example functionalizing or modifying a surface to achieve a required technical effect, or coating a surface with a thin film polymer layer. Functionalizing or modifying a surface may be carried out using a non-polymerisable gas. The embodiments herein described relate specifically to treatment including a coating step but it will be apparent that the embodiments are applicable to other types of treatment steps, if necessary with minor changes to the apparatus.

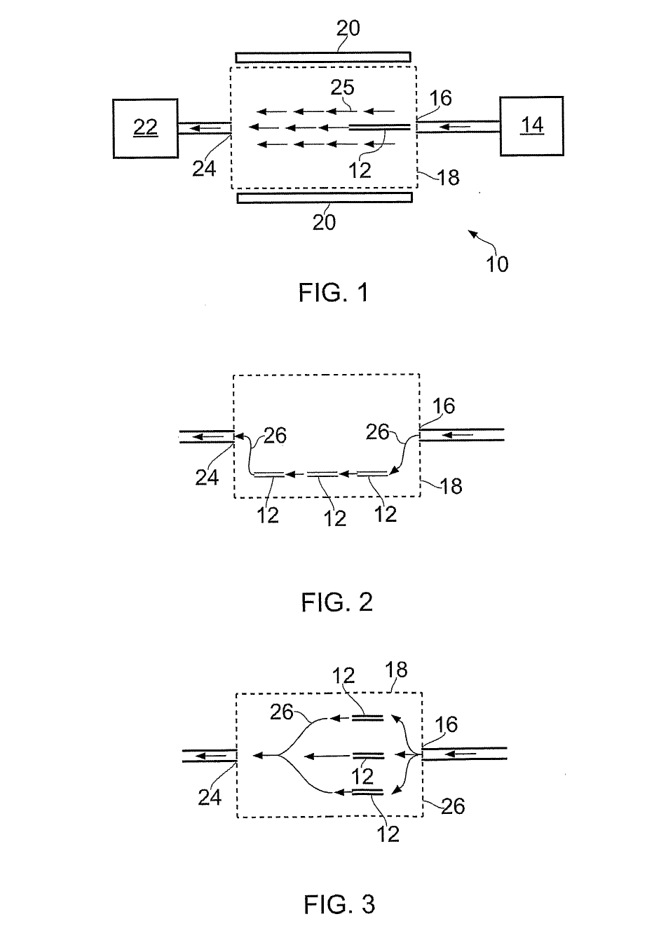

Referring to FIG. 1, apparatus 10 is shown for coating a surface of a small channel 12 with a thin film polymer layer by plasma deposition, the apparatus 10 comprising: a source 14 of active species for supply to an inlet 16 of a processing region 18 for forming a plasma in the processing region, or within small channel 12; means 20 for applying an electric field to the active species in the processing region so that a plasma is formed; and vacuum pumping means 22 for connection to an outlet 24 of the processing region, the vacuum pumping means being operable to provide a flow path 26 in the processing region from the inlet to the outlet thereof and to control pressure in the processing region. Apparatus 10 further comprises supporting means (not shown in FIG. 1) for supporting at least one small channel so that, in use, said flow path extends therethrough, and an internal surface of said at least one small channel is coated with a thin film polymer layer by plasma deposition.

The apparatus 10 is suitable for use with many different types of small channels which are closed around their circumference and have an internal cross-sectional width less than about 10 mm, such as for example catheters, vascular grafts, enteral feeding tubes or devices with a narrow channel, for example hyper-dermic needles. Such small channels may be linear or have a tortuous path, and have a circular, polygonal or irregular cross-section.

The invention however, is not limited to small channels of any particular width, but rather the invention has utility in processing an internal surface of small channels which would otherwise not be effectively processed using known apparatus because insufficient active species or plasma is caused to enter through the small channel to permit consistent and reliable processing of its surface.

In the embodiments of the invention described herein, the flow path generated between the inlet and outlet of the processing region is caused to pass through the small channel so that sufficient deposition can take place. The flow path may be guided through the small channels by flow guide means or supported in such a position as to promote the passage of active species or plasma through the small channels. Suitable exemplary support means are described herein. A modification to this embodiment allows media to reside within the small channel, for instance if the small channel is to form part of a filtration product.

The thin film polymer layer deposited on a surface of the small channels may produce any desired or advantageous technical effect such as to render the article hydrophobic or oleophobic.

The active species is typically a monomer, stored in a monomer tube, which undergoes polymerisation on a surface of the article when the monomer breaks down and forms a plasma. In addition polymerisation will occur when not activated species pass over an activated site where conventional free radical polymerisation through propagation can occur.

Referring to the Figures, means 20 for applying an electric field to the active species may comprise a plurality of electrode plates or one or more induction coils, or other so that an electric field is generated in the processing region, in small channel 12 or remote to it, which causes active species to breakdown internally of the small channels or externally if required and deposition to occur at their surface. Whether electrode plates or induction coils or other are used depends on the particular arrangement of the apparatus and the material of the small channels, through-put requirements and chamber size.

If induction coils are used, a time varying electric current is supplied to the coils. An L-C matching unit and a power meter may be used to couple the output of a 13.56 MHz radio frequency (RF) generator connected to a power supply. This arrangement ensures that the standing wave ratio (SWR) of the transmitted power to reflected power is maximised. For pulsed plasma deposition, a pulsed signal generator can be used.

In FIG. 1, the processing region is of indefinite size and shape and may be defined by for example a processing chamber or the small channels themselves.

Vacuum pumping means 22 can be selectively placed in fluid communication with the outlet of the processing region so that the pressure can be reduced to appropriate processing pressures required for plasma deposition. Typically, such pressures are in the range of 1×10⁻⁵ torr to 1 torr (approximately 1×10⁻⁸ to 1×10⁻³ bar), however, pressures outside this typical range may be required. Vacuum pumping means 22 may comprise a high pressure pumping, or backing, unit for reducing pressure from atmosphere to a first, or intermediate, pressure and a low pressure pumping unit for reducing pressure from the first pressure to a processing pressure. The high pressure pumping unit may suitably be a roots pump. The low pressure pumping unit may suitably be a turbo molecular pump.

The vacuum pumping means 22 is operable to cause a flow path from the inlet of the processing region through one or more small channels for processing and to the outlet of the processing region. The flow of active species from source 14 and the power supplied to vacuum pumping means 22 is selected to control an appropriate flow path through the small channels so that effective plasma deposition occurs. That is, increased flow may be provided by increasing the mass flow rate of active species supplied from source 14 such that active species or plasma more efficiently enters the small channels. In this regard, the arrangement may be configured such that a pressure differential exists between the inside of the small channels and the processing region so that active species or plasma is encouraged to flow along a pressure gradient from the processing region into the small channels.

Referring to FIGS. 2 to 6, supporting means are provided for supporting a plurality of small channels 12 so that the flow path 26 extends through each small channel and the internal surface of each of the channels can be coated with a thin film polymer layer by plasma deposition. The supporting means may take any suitable form such as a platform adapted to position the small channels in the flow path or a synthetic plastics moulding adapted to support and guide the flow path into and out of each small channel.

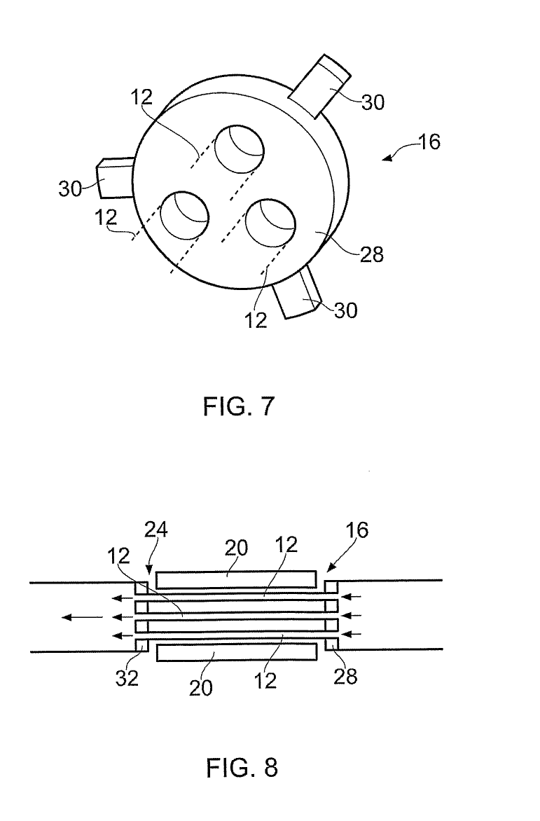

A number of examples of the supporting means are described in greater detail with reference to FIGS. 7 to 11. FIGS. 2 to 6 show exemplary arrangements of small channels which fall within the scope of the present invention. Such arrangements, or combinations thereof, can be incorporated in any of the apparatus described herein.

In FIG. 2, three small channels 12 are arranged in series so that the flow path 26 extends through the channels in succession. The arrangement may comprise a flow guide for guiding flow to the most upstream small channel from the inlet 16 of the processing region 18 and flow connectors for connecting each small channel so that the flow path is guided from one small channel to the next downstream channel in succession. Once the flow path exits the most downstream small channel it is exhausted through the outlet 24 of the processing region. Although three small channels are shown in series more or less small channels can be provided in series as required.

In FIG. 3, three small channels 12 are arranged in parallel and the flow path 26 is divided into a plurality of flow paths which extend through respective small channels. The arrangement may comprise a flow guide for dividing the flow path from the inlet 16 of the processing region 18 and guiding flow to each small channel 12. Once the flow path exits each small channel it is exhausted through the outlet 24 of the processing region. Although three small channels are shown in parallel, more or less small channels can be provided in parallel as required.

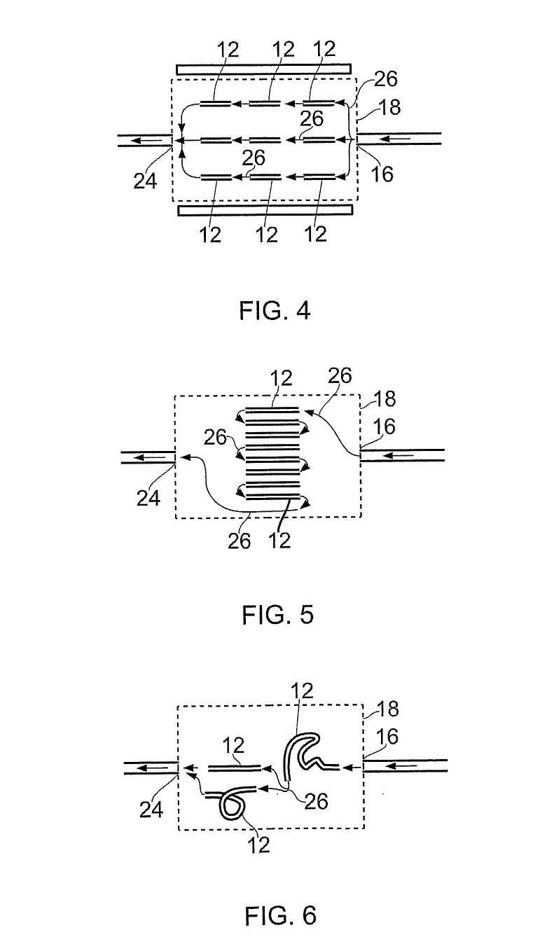

FIG. 4 shows an arrangement in which nine small channels are disposed in both series and parallel.

FIG. 5, which is similar to FIG. 2, shows an arrangement of eight small channels in which the flow path is caused to adopt a tortuous path in which it extends through a first small channel generally in one direction and through a subsequent small channel in a generally opposing direction. This arrangement may be similar to a filtration unit

FIG. 6 shows three small channels 12 arranged in series and parallel along a flow path 26 as is the case in FIG. 4. However, the small channels in FIG. 6 are of dissimilar size and shape one from another, and two of the small channels are also of irregular configuration.

Any combination of two or more of the arrangements shown in FIGS. 2 to 6 can be adopted as required.

FIG. 7 shows in more detail one example of supporting means for supporting at least one small channel 12 so that, in use, the flow path 26 extends therethrough, and an internal surface of said at least one small channel is coated with a thin film polymer layer by plasma deposition. In the example the supporting means comprises an inlet support 28, of general circular cylindrical configuration for supporting three small channels at the inlet 16 of the processing region 18. The inlet support 28 has fixing means 30 for fixing the support at the inlet of the processing region so that the flow path extends into the one or more channels when the apparatus is in use. The fixing means 30 shown in FIG. 7 comprises three keys spaced about a circumference of the inlet support 28 for locking with three complimentary locking recesses (not shown) at the inlet 16. A seal such as an O-ring may be used to seal between the inlet support and the inlet 16.

Alternatively, the inlet support 28 can be permanently or semi-permanently fixed in place at the inlet 16. However, one advantage of an inlet support which can be readily fixed and unfixed from position is that apparatus 10 may comprise a plurality of inlet supports each with apertures sized and shaped to receive and support a particular small channel so that small channels with any one of a plurality of sizes and shapes can be supported at the inlet 16.

Inlet support 28 comprises three apertures sized and shaped to receive and support three small channels 12 (shown in broken lines). Each aperture may be provided with a seal such as an o-ring to seal between the small channel and the inlet support. The small channels are supported by the inlet support in a cantilever arrangement.

Apparatus 10 may in addition to or as an alternative to an inlet support comprise an outlet support (shown in FIG. 8) for supporting one or more small channels at the outlet of the processing region. Such an outlet support may have fixing means for fixing the support at the outlet so that the flow path extends into the one or more channels when the apparatus is in use. Further details of the outlet support are equivalent to those of the inlet support mutatis mutandis.

FIG. 8 shows apparatus 16 comprising an inlet support 28 and an outlet support 32. Three small channels 12 are supported at end portions thereof by the inlet support 28 and the outlet support 32. It will be apparent that the processing region 18 is not shown in broken lines in FIG. 8 since the processing region is defined by an internal surface of each of the small channels 12. In this regard, vacuum pumping means 22 (not shown in FIG. 8) is operable to provide a flow path 26 in the small channels from the inlet to the outlet thereof and to control pressure in the small channels. The small channels should be able to resist a pressure differential which may be atmosphere externally to the small channels and processing pressure internally thereto.

Means 20 are shown for applying an electric field to the active species in the small channels so that a plasma is formed when the apparatus is in use.

Where compatible, any of the arrangements shown in FIGS. 2 to 6 can be combined with the arrangement shown in FIG. 8 if required.

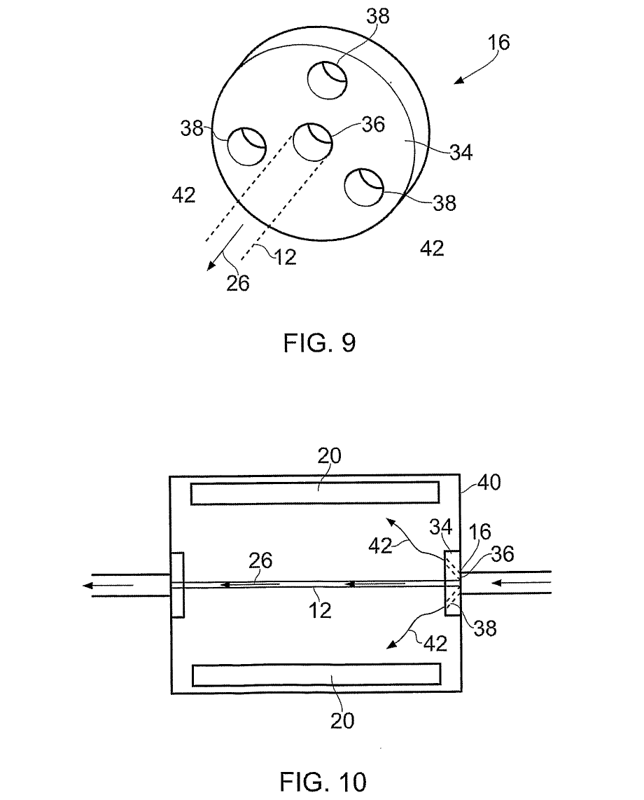

A modified version of the inlet support 28 is shown in FIGS. 9 and 10. The modified inlet support 34 comprises at least one aperture 36 sized and shaped to receive a small channel 12 (shown in broken lines) to allow the flow path 26 to extend therethrough, and an internal surface of the channel to be coated with a thin film polymer layer by plasma deposition. In FIG. 10, the processing region is defined by a processing chamber 40. The inlet support also comprises at least one further aperture 38 for allowing active species to enter the processing chamber as shown by arrows 42. Accordingly, the flow path 26 extends through the small channel 12 and the flow path 42 is external to the small channel so that the internal surface and an external surface of the small channel can be coated with a thin film polymer layer by plasma deposition.

Only one small channel is shown in FIGS. 9 and 10, but it will be appreciated that more than one small channel can be configured as shown so that both an internal and external surface can be coated.

The apparatus shown in FIG. 11 comprises a first source 14 of active species and a second source 44 of active species wherein active species from the first source is supplied along the flow path 26 through the or each small channel 12 so that the internal surface of the or each of the small channels can be coated with a thin film polymer layer from plasma formed from the active species from the first source 14 and wherein active species from the second source 44 is supplied along the flow path 46 externally to the or each small channel 12 so that the external surface of the or each of the small channels can be coated with a thin film polymer layer from plasma formed from the active species from the second source 44.

The functional properties exhibited by coatings formed from the active species from the first source 14 and from the active species from the second source 44 may be different. For instance, one of the internal surface and external surface may be hydrophilic whilst the other is hydrophobic.

Gas or plasma is exhausted from the processing chamber at a first outlet 24 for flow path 26 and at a second outlet 48 for flow path 46. The vacuum pumping means may therefore be controlled to cause different processing pressures internally of the small channels and externally of the small channels. This arrangement is advantageous if the active species from each of the first and second sources require different processing pressures or flow rates.

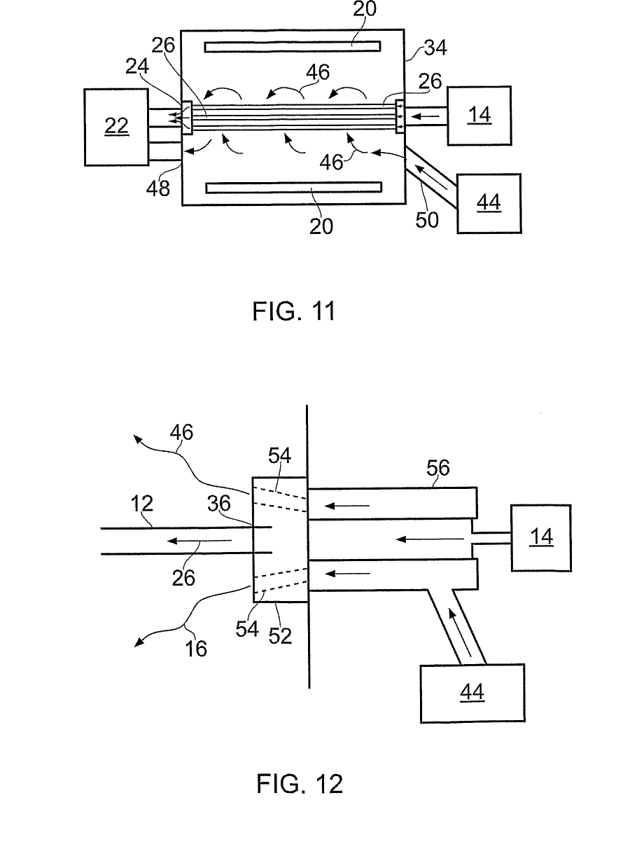

FIG. 11 shows a second inlet 50 for feeding active species into the processing chamber 34 from the second source 44. An alternative to this arrangement is shown in FIG. 12. In FIG. 12, a modified inlet support 52 comprises an aperture 36 sized and shaped to receive and support a small channel 12 to allow a flow path 26 from the first source 14, and apertures 54 which are open and communicate with an annular passage 56 to allow a flow path 46 from the second source 44 so that internal surface and external surface of the or each of the small channels can be coated with a thin film polymer layer by plasma deposition.

The invention has been described by way of various embodiments, with modifications and alternatives, but having read and understood this description further embodiments and modifications will be apparent to those skilled in the art. All such embodiments and modifications are intended to fall within the scope of the present invention as defined in the accompanying claims.

1. Apparatus for treating a surface of a small channel by plasma, comprising:
a source of active species for supply to an inlet of a processing region for forming a plasma in said processing region;
means for applying an electric field to an active species in said processing region or channel so that a plasma is formed;
vacuum pumping means for connection to an outlet of said processing region, said vacuum pumping means being operable to provide a flow path in said processing region from said inlet to said outlet thereof and to control pressure in said processing region; and
supporting means for supporting at least one small channel so that, in use, said flow path extends therethrough, and an internal surface of said at least one small channel is treated by plasma processing.

2. Apparatus for treating a surface of a small channel by plasma as claimed in claim 1, wherein:
in use, said flow path extends through each of a plurality of small channels so that an internal surface of each of said channels can be treated by plasma processing.

3. Apparatus for treating a surface of a small channel by plasma as claimed in claim 2, wherein:
in use, said plurality of small channels are arranged in series so that said flow path extends through said channels in succession.

4. Apparatus for treating a surface of a small channel by plasma as claimed in claim 2, wherein:
in use, said plurality of small channels are arranged in parallel and said flow path is divided into a plurality of flow paths which extend through respective small channels.

5. Apparatus for treating a surface of a small channel by plasma as claimed in claim 4, further comprising:
an inlet support for supporting one or more small channels at said inlet of said processing region:
wherein said support has fixing means for fixing said support at said inlet of said processing region so that said flow path extends into said one or more channels when said apparatus is in use.

6. Apparatus for treating a surface of a small channel by plasma as claimed in claim 5, further comprising:
an outlet support for supporting one or more small channels at said outlet of said processing region:
wherein said support has fixing means for fixing said support at said outlet so that said flow path extends into said one or more channels when said apparatus is in use.

7. Apparatus for treating a surface of a small channel by plasma as claimed in claim 6, wherein:
said processing region is defined by an internal surface of at least one small channel extending from said support at said inlet to said support at said outlet.

8. Apparatus for treating a surface of a small channel by plasma as claimed in claim 6, wherein:
said processing region is defined by a processing chamber into which at least one small channel can be disposed along a flow path when said apparatus is in use so that an internal surface of said or each of said small channels can be treated by plasma processing.

9. Apparatus for treating a surface of a small channel by plasma as claimed in claim 8, wherein:
said flow path extends through said or each of said small channels and externally to said the or each of said small channels so that said internal surface and an external surface of said or each of said small channels can be treated by plasma processing.

10. Apparatus for treating a surface of a small channel by plasma as claimed in claim 9, further comprising:
a first source of active species and a second source of active species;
wherein active species from said first source is supplied along said flow path through said or each of said small channels so that said internal surface of said or each of said small channels can be treated by plasma formed from said active species from said first source: and
wherein active species from said second source is supplied along said flow path externally to said or each of said small channels so that said external surface of said or each of said small channels can be treated by plasma formed from said active species from said second source.

11. (canceled)

12. Apparatus for treating a surface of a small channel by plasma as claimed in claim 11, wherein:
said fixing means of said inlet support is adapted to fix said inlet support at an inlet of said processing chamber; and
wherein, in use, at least one aperture of said inlet support receives and supports a small channel and at least one aperture is open allowing active species to flow into said processing region so that said internal surface and an external surface of said or each of said small channels can be treated by plasma processing.

13. Apparatus for treating a surface of a small channel by plasma as claimed in claim 12, wherein said treating by plasma processing comprises:
coating a surface of said small channel with a thin film polymer layer.
